(19) United States
(12) Patent Application Publication
(10) Pub. No.: US 2024/0138104 A1
(43) Pub. Date: Apr. 25, 2024

(54) STACKED-FIN COLD PLATE WITH A 3D VAPOR CHAMBER

(71) Applicant: STRATEGIC THERMAL LABS, LLC, Leander, TX (US)

(72) Inventor: AUSTIN SHELNUTT, GEORGETOWN, TX (US)

(21) Appl. No.: 18/493,769

(22) Filed: Oct. 23, 2023

Related U.S. Application Data
(60) Provisional application No. 63/418,932, filed on Oct. 24, 2022.
(60) Provisional application No. 63/418,938, filed on Oct. 24, 2022.
(60) Provisional application No. 63/418,948, filed on Oct. 24, 2022.

(51) Int. Cl. H05K 7/20

(52) U.S. Cl. CPC H05K 7/20254; H05K 7/20772

(57) ABSTRACT

A cold plate assembly includes a thermally conductive cold plate having a first surface attachable to a heat generating electronic component of an information processing system. An opposite second surface includes an array of hollow riser columns extending orthogonally and filled with a saturated working fluid for heat transfer. The cold plate assembly includes a stacked arrangement of fins physically attached perpendicularly to at least one of the riser columns. The vertical levels of fins are spaced apart, substantially in parallel with each other and the second surface to form a fin stack. An encapsulating lid of the cold plate assembly is attached to the second surface to form a liquid cooling cavity that encloses the fin stack. The encapsulating lid includes an intake port and an exhaust port that are laterally positioned and aligned with the fin stack to create liquid flow through the fin stack for liquid cooling.

### CROSS-REFERENCE TO RELATED APPLICATIONS

The present application claims the benefit under 35 U.S.C. § 119 of the following U.S. Provisional patent applications, each filed on 24 Oct. 2022: (i) Ser. No. 63/418,932 entitled “Environmentally Hardened Cold Plate for Use in Liquid Cooling with Suboptimal Water Quality”; (ii) Ser. No. 63/418,938 entitled “Smart Rack Liquid Manifold”; and (iii) Ser. No. 63/418,948 entitled “Stacked-Fin Cold Plate using a 3D Vapor Chamber”, the disclosures of which are hereby incorporated by reference in their entirety.

### BACKGROUND

### 1. Technical Field

The present application relates generally to heat transfer mechanisms used for cooling electronic devices, and more particularly, to liquid cooling apparatuses for removing heat generated by one or more electronic devices.

### 2. Description of the Related Art

Recent trends in global digital transformation have created incredible demand for increased processing performance in colocation and edge deployments of data/information processing servers. Datacenters today rely upon high power microprocessor devices, such as central processors (CPUs) and graphic processing units (GPUs), which generate a high level of heat in a small area. Traditional use of air as the heat transfer medium to cool heat dissipating components is unable to meet the thermal dissipation requirement of these high power microprocessor devices. Thus, liquid cooling using cold plates have become a preferred way to provide the required cooling. Cold plates are a type of heatsink that allows for a liquid coolant to be brought into thermal conduction contact with the heat-generating electronic components of servers and other information processing systems. These cold plates rely upon ultra-narrow fluid passages called “microchannels” to dissipate heat from the processors into the liquid coolant. The microchannels typically have hydraulic diameters of less than 1-mm and are arranged with fin spacing that is 0.2-0.4-mm. With such small fin spacings, problems related to fin fouling can occur due to fin surface corrosion and solid particulate build-up within the microchannels. Microchannels that get plugged by contaminated water or by surface corrosion growth can no longer be utilized for efficient liquid heat transfer as the cold plate decreases in cooling efficacy.

One challenge of constructing cold plates is that, unlike air-cooled heatsinks, liquid coolants have extremely high heat transfer coefficients that create diminished returns on fin height (commonly referred to as fin efficiency) because it is difficult to conduct heat through narrow passages using conventional metals. Fin efficiency limits typically result in cold plate fin heights that are less than 4 mm. This means that cold plates are effectively a two-dimensional heat sink. Historically, being limited to the surface area possible in just two dimensions has not been an issue for cold plates because the liquid heat transfer performance is so high compared to air. Future central processing units (CPUs) and application specific integrated circuits (ASICs) are challenging that paradigm as these devices will require even more cooling than a standard fin geometry provides.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 presents a three-dimensional disassembled view of a cold plate assembly and a heat generating electronic component, the cold plate assembly including an encapsulating lid and a cold plate with hollow orthogonal riser columns that support a fin stack for increased surface area for thermal transfer, according to one or more embodiments;

FIG. 2 is a three-dimensional view of an example fin stack having flat fins attached to the array of riser columns of the cold plate of FIG. 1, according to one or more embodiments;

FIG. 3 is a three-dimensional view of an assembled cold plate assembly including the example cold plate with fin stack of FIG. 2 enclosed by an example transparent encapsulating lid to provide a volumetric liquid cooling cavity/enclosure with attached heat generating electronic component, according to one or more embodiments;

FIG. 4 is a three-dimensional cutaway view of a cold plate assembly attached to the heat generating electronic component and including a second example fin stack comprised of annular disk fins around each riser column, according to one or more embodiments;

FIG. 5 is a three-dimensional view of a cold plate attached to a third example fin stack having dimpled fins, according to one or more embodiments;

FIG. 6 is a three-dimensional view of a cold plate attached to a fourth example fin stack comprised of corrugated fins, according to one or more embodiments;

FIG. 7 is a three-dimensional cutaway view of a cold plate assembly including the fourth example fin stack comprised of corrugated fins of FIG. 11 and attached to a heat-generating electronic component, according to one or more embodiments;

FIG. 8A is side detailed view of a cutaway portion of the cold plate and a single orthogonal riser column of FIG. 7, according to one or more embodiments;

FIG. 8B is a three-dimension view of a hollow interior cavity of a single orthogonal riser column of FIG. 7, according to one or more embodiments;

FIG. 9 is a top view diagram of liquid flow from the intake port of the example cold plates of FIGS. 1-7, through the two separated adjacent sections, out the adjacent exhaust port, according to one or more embodiments;

FIG. 10 is a side view diagram of an information processing system including the heat generating electronic component with attached cold plate assembly of FIG. 1 with opposing intake and exhaust ports, according to one or more embodiments;

FIG. 11 is a diagram of a first example liquid cooling system that supports a datacenter equipment center utilizing one liquid cooling loop for rack-level liquid cooling of heat generating electronic components attached to one of the cold plate assembly of FIG. 1, according to one or more embodiments;

FIG. 12 illustrates a physical vapor deposition (PVD) process for covering a cold plate and fin stack with a protective coating, which protects the cold plate and fin stack from damage, deterioration, and/or clogging due to exposure to facility-grade cooling liquids, according to one or more embodiments;

FIG. 13 is a flow diagram presenting a method of manufacturing a cold plate assembly having increased thermal energy dissipation capabilities of a fin stack attached to 3D vapor chambers, according to one or more embodiments;

FIG. 14 is a flow diagram presenting a method that augments the method of FIG. 13 to environmentally hardening a fin stack and other wetted surfaces of the cold plate assembly that may be exposed to cooling liquid to enable utilizing facility-grade liquid for liquid cooling of heat generating electronic components, without experiencing issues of fouling or clogging, according to one or more embodiments; and

FIG. 15 is a flow diagram presenting a method of using a cold plate assembly to liquid cool heat generating components of an information processing system, according to one or more embodiments.

### DETAILED DESCRIPTION

The present disclosure provides a cold plate assembly that provides increased rate of thermal energy transfer during liquid cooling of an attached heat generating electronic component by utilizing a vertical fin stack presenting increased fin surface area for thermal dissipation to the cooling liquid and riser columns configured as 3-dimensional (3D) vapor chambers for engaging the fin stack and for providing increased thermal conductivity from the heat generating electronic component using phase change heat transfer. The cold plate is made of a thermally conductive material. The cold plate has a first surface attachable to the heat generating electronic component of an information processing system. The cold plate has a second surface opposite to the first surface. The cold plate has an array of more than one riser columns extending orthogonally from the second surface of the cold plate. The cold plate includes a stacked arrangement of two or more levels of fins that are physically attached to at least one of the more than one riser columns, perpendicular to the at least one of the more than one riser columns. The two or more levels are spaced apart, substantially in parallel with each other and with the second surface, to form a fin stack. The cold plate assembly includes an encapsulating lid attachable to the second surface to form a liquid cooling cavity that encloses the riser columns and fin stack. The encapsulating lid includes an intake port and an exhaust port that are laterally positioned and aligned with the fin stack to create liquid flow through the fin stack for liquid cooling.

According to a second aspect of the present disclosure, an information processing system includes at least one heat generating electronic component that requires an increased dissipation of thermal energy via liquid cooling than possible with microchannels formed on a conventional cold plate. The information processing further includes a cold plate assembly configured with 3D riser columns supporting a fin stack having the requisite surface area and heat transfer characteristics to achieve the liquid cooling requirements.

According to a third aspect of the present disclosure, a data center includes an information processing system rack that supports the information process system having the at least one heat generating electronic component and a connected one of the cold plate assemblies described herein.

According to a fourth aspect of the present disclosure, a method is disclosed of manufacturing of a stacked fin cold plate with 3D vapor columns for providing liquid cooling of heat generating electronic components. In one or more embodiments, the method includes physically attaching a stacked arrangement of two or more levels of fins that are to at least one of more than one riser columns of a cold plate perpendicular to the at least one of the more than one riser columns. The two or more levels of fins are spaced apart and substantially in parallel with each other to form a fin stack. The riser columns are configured as 3D vapor chambers containing a saturated working fluid that undergoes phase changes to facility the heat transfer from the heat generating electronic component and the heat dissipation via conduction to the fin stack and cooling liquid. The cold plate is made of a thermally conductive material. The cold plate has a first surface attachable to a heat generating electronic component of an information processing system. The cold plate has a second surface substantially in parallel to the fin stack, opposite to the first surface, and including the more than one riser columns, which extend orthogonally from the second surface of the cold plate. The method includes attaching an encapsulating lid to the second surface to form a cold plate assembly having a liquid cooling cavity that encloses the fin stack and riser columns. The encapsulating lid includes an intake port and an exhaust port that are laterally positioned and aligned with the fin stack to create liquid flow through the fin stack for liquid cooling.

Future central processing units (CPUs) and application specific integrated circuits (ASICs) are pushing past the current boundaries of heat generation during information processing within an information processing system. While liquid cooling is the preferred method for addressing the high thermal yields of these devices, the standard fin geometries of conventional cold plates have a limited surface area in a relative 2-dimensional (2D) space and thus cannot provide sufficient cooling for these devices as the devices increase their thermal output. Creating larger surface area on a conventional 2D cold plate, geometrically requires creating ever smaller and smaller fin spacings. Current technology allows manufacturers to create 0.2-0.44 mm channels which, while ideal for 2D heat transfer, are very intolerant of debris, particles, and corrosion agents within the liquid coolant, necessitating specialized water quality control via secondary coolant loop (i.e., technology cooling system (TCS)). The limits of these conventional system have been reached. The present disclosure addresses and overcomes these limitations in existing cold plate technology by re-orienting the direction of the fins to provide even larger fin surface area for liquid cooling, while maintaining the dimensions of the cold plate footprint. Additionally, the present disclosure provides more efficient heat absorption and thermal dissipation from the attached heat generating electronic component by providing phase change heat transfer using a saturated working fluid within a phase change cavity within each of the riser columns. Accordingly, the cold plate assembly provides a more efficient heat exchange mechanism for use within a liquid cooling loop of a datacenter facility or other operating environment.

One of the challenges with using cold plates to provide liquid cooling of electronic components within a data center or server rack is the need for use of a complex system of multiple loops of cooling liquid dues to the sensitive nature of the cold plate, which is susceptible to corrosion and clogging if exposed to a flow of regular liquid. During liquid cooling, the applied liquid flows through the microchannels between the heated fins of the cold plate to absorb the heat being conducted from the attached heat generating component. In order to prevent these microchannels and the fins from fouling due to corrosion or from solid particulate within the cooling liquid, cold plate solution providers generally require the use of tightly controlled secondary coolant with optimized chemical properties to inhibit corrosion and prevent biological growth, and which has been filtered of fluid-borne particulate. The secondary coolant, which is referred to as a technology coolant supply (TCS) flows through a loop of conduits that is coupled to the less tightly controlled facility water supply (FWS) via a liquid-to-liquid heat exchanger, typically housed within a coolant distribution unit (CDU). The CDU effectively isolates the cold plates from hazardous water quality. In addition to cost and complexity of implementation, one additional penalty or drawback of this multi-loop system is the fluid temperature gradient between the FWS and the TCS. This temperature gradient, which is sometimes called the “approach temperature”, demands, according to thermodynamic laws, that the TCS always be warmer than the FWS when cooling information processing systems. This temperature gradient creates energy inefficiencies by forcing the FWS temperatures to have to be lowered so that the TCS temperatures stay within the specification of the microprocessor cold plate. This can limit cooling capacity of the achievable power utilization effectiveness (PUE) of the cooling solution. The present disclosure overcomes these deficiencies in the existing liquid cooling solutions by providing/manufacturing a cold plate and a corresponding cold plate assembly and liquid cooling system that are resistive to the fouling from direct exposure to facility water and thus enables the data center cooling solution to be provided with a single cooling loop utilizing the facility water supply.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical, and other changes may be made without departing from the spirit or scope of the present disclosure. The following detailed description is, therefore, not to be taken in a limiting sense, and the scope of the present disclosure is defined by the appended claims and equivalents thereof. Within the descriptions of the different views of the figures, similar elements are provided similar names and reference numerals as those of the previous figure(s). The specific numerals assigned to the elements are provided solely to aid in the description and are not meant to imply any limitations (structural or functional or otherwise) on the described embodiment. It will be appreciated that for simplicity and clarity of illustration, elements illustrated in the figures have not necessarily been drawn to scale. For example, the dimensions of some of the elements are exaggerated relative to other elements.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that term is utilized. As a specific example, reference is made herein to the term facility liquid, facility water, facility cooling liquid, facility-grade cooling liquid, and cooling liquid. It is appreciated that the terms facility liquid or facility cooling liquid are utilized to provide a specific example of a cooling liquid supplied by/at a datacenter facility in which the heat generating electronic components are operating and being cooled in a single liquid cooling loop that includes facility liquid, which is typically unpurified water. Facility-grade cooling liquid is a more general term that can apply to both cooling liquid that is being provided at a datacenter facility or any other cooling liquid that can contain contaminants and particulates, similar to the normal facility liquid found in datacenters. Thus, facility-grade cooling liquid can apply to any type of liquid, regardless of the source of the liquid, and can also apply to liquid cooling that is not provided at a “facility” or datacenter. The descriptions herein are meant to apply to any type of facility-grade cooling liquid. Additionally, it is appreciated that the cooling liquid utilized within the cooling loop that includes the described cold plate assembly can also be a higher-grade cooling liquid than facility-grade cooling liquid, without limitation.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention. The description of the illustrative embodiments can be read in conjunction with the accompanying figures. Embodiments incorporating teachings of the present disclosure are shown and described with respect to the figures presented herein.

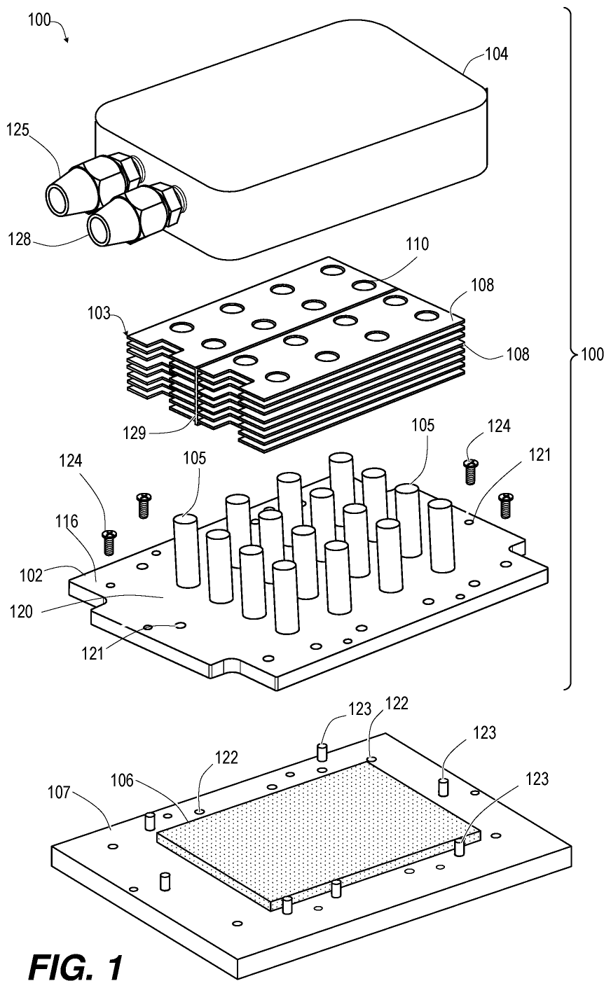

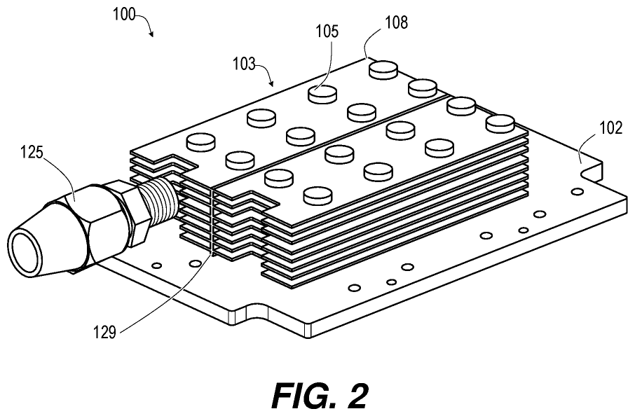

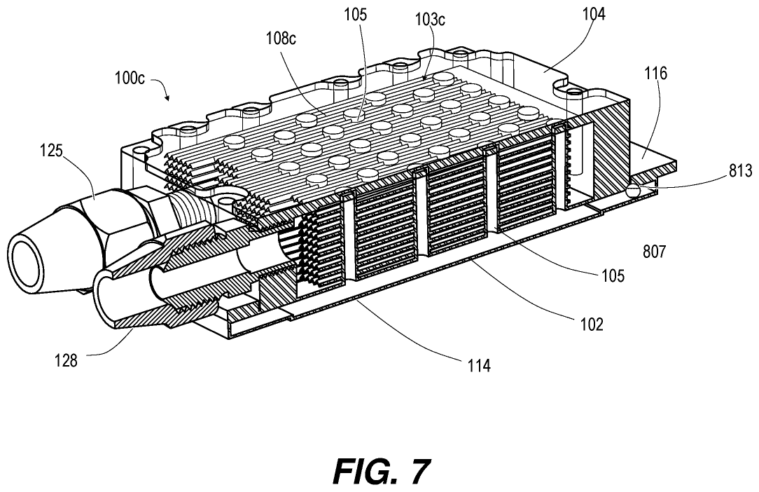

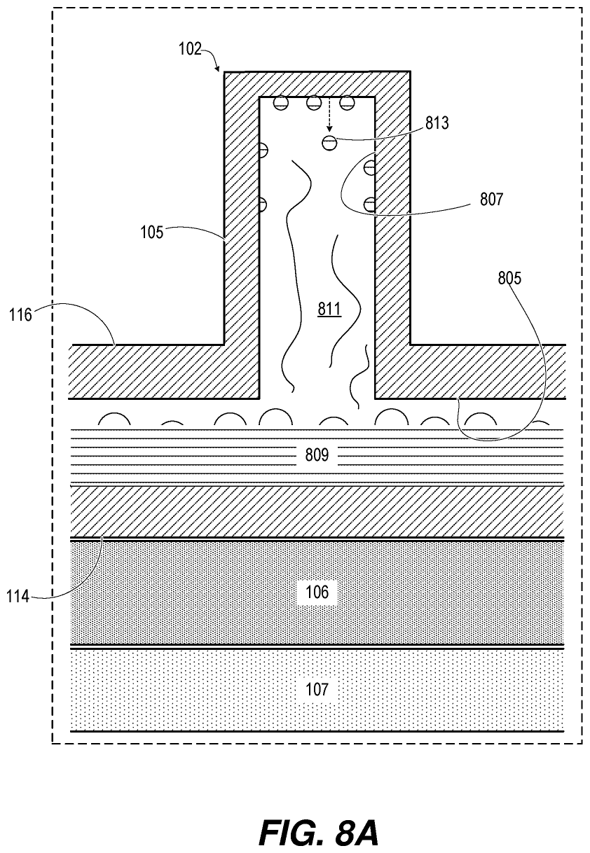

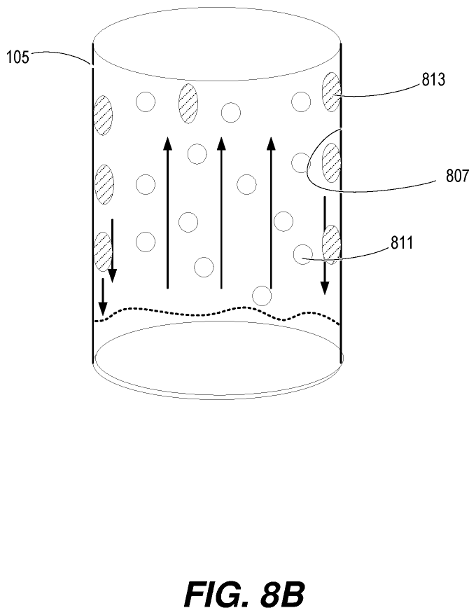

FIG. 1 presents a three-dimensional disassembled view of example cold plate assembly 100 including cold plate 102, fin stack 103, and encapsulating lid 104, for use with example heat generating electronic component 106, which receives liquid cooling via cold plate assembly 100. First surface 114 (FIGS. 7 and 8) of cold plate 102 is attached in thermal contact to heat generating component 106. Cold plate 102 has an array of orthogonal riser columns 105, which are configured as hollow pipes or tubes containing a saturated working fluid utilized to aid in heat transfer from the heat generating electronic component. Riser columns 105 extend away from second surface of cold plate extending the height dimension of cold plate to allow for increased volume for fin placement, thus increasing fin surface area for thermal transfer. In an example embodiment, heat generating electronic component 106 is an integrated circuit module, such as a central processing unit (CPU) or graphics processing unit (GPU) placed/manufactured on substrate 107 (e.g., a circuit board). In another example embodiment, heat generating electronic component 106 is an electrical power conversion or regulation component. Each fin 108 of fin stack 103 has one or more holes 110 that are sized to receive (i.e., fit over) one of the more than one riser columns 105. Referring to FIG. 2, there is presented a three-dimensional view of example fin stack 103 having fins 108 that are flat and attached to the array of riser columns 105 of the cold plate of FIG. 1. Fins 108 are perpendicular to the at least one of the more than one riser columns 105. The two or more levels of fins 108 are spaced apart, substantially in parallel with each other and with second surface 116 to form fin stack 103.

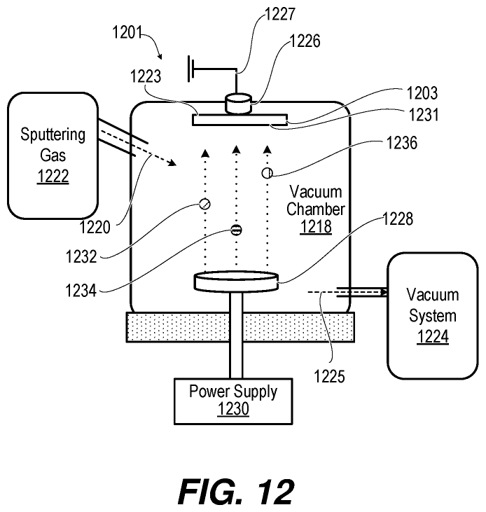

With ongoing reference to FIG. 1, example cold plate 102 is formed from a conductive material such as copper. In one or more embodiments, cold plate 102, including orthogonal riser columns 105 and fan stack 103 are environmentally hardened, such as in physical vapor deposition (PVD) apparatus described below with reference to FIG. 12, to withstand fouling and/or clogging due to direct use of facility or facility-grade water to provide liquid cooling. Unlike conventional devices, environmentally hardened cold plate 102, with the protective surface coating, is tolerant of poorly controlled water quality (including from both chemical contaminants and particulates).

According to one additional aspect, fin stack 103 is constructed with flow plate geometry that is designed to prevent flow obstruction by particulate suspended in the liquid coolant. The geometry of the cold plate flow passages is designed to promote heat transfer efficiency that is similar to conventional electronic cooling cold plates typically manufactured from bare copper or nickel-plated copper. Fins 108 in fin stack 103 may be spaced apart at least 800-microns to facilitate passage of the facility liquid particulates. In one or more embodiments, in manufacturing fin stack 103, a geometry and spacing of each fin 108 may be configured to maintain large hydraulic diameters with greater than 800-micron flow spaces.

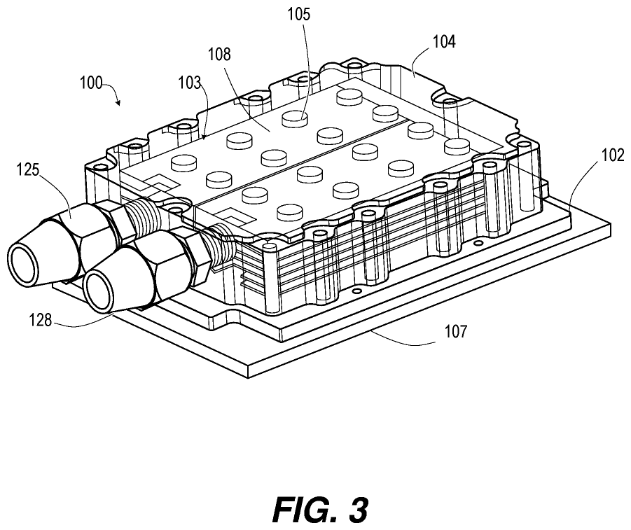

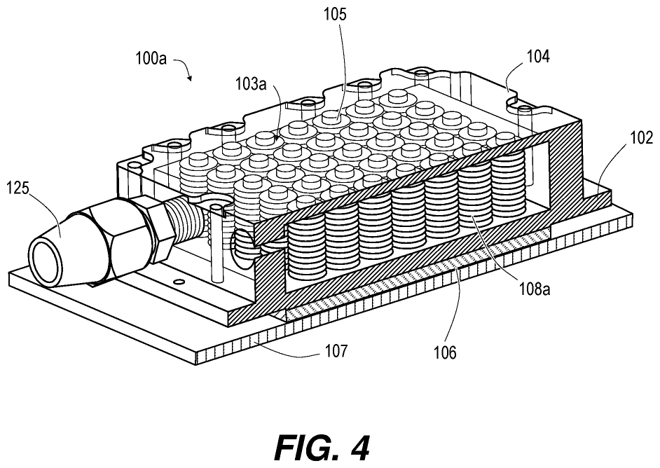

Additional features of cold plate assembly 100 of FIG. 1 and FIG. 2 will be described with reference to FIGS. 3 and 4. FIG. 3 is a three-dimensional view cold plate assembly 100 attached above heat-generating electronic component 106 (FIG. 1) with substrate 107 being visible. Encapsulating lid 104 of cold plate assembly 100 is depicted as illustrated with additional contour details and is attached on top of cold plate 102. Encapsulating lid 104 includes intake port 125 and exhaust port 128. As shown by FIG. 2, intake port 125 includes grooves for screwably attaching or inserting into a first of two holes presented in a surface of encapsulating lid 104.

Second surface 116 includes perimeter 120 around the array of orthogonal riser columns 105 for mounting of encapsulating lid 104. In one or more embodiments, perimeter 120 is recessed into second surface 116 to facilitate sealing attachment of encapsulating lid 104 to cold plate 102. Sealably attaching encapsulating lid 104 to cold plate 102 may include use of one or more of a press-fit interference attachment, an adhesive layer, soldering, brazing, welding, and a fastener attachment.

Through holes 121 pass orthogonally through first and second surfaces 114 (FIG. 3) and 116 of cold plate 102. A subset of holes 122 in substrate 107 receive guide pins 123 that are aligned with corresponding through holes 121 in cold plate 102 to guide assembly of cold plate 102 to substrate 107. Holes 122 in substrate 107 surrounding heat generating component 106 align with other through holes 121 for receiving a respective machine screw 124 to attach cold plate assembly 100 to substrate 107.

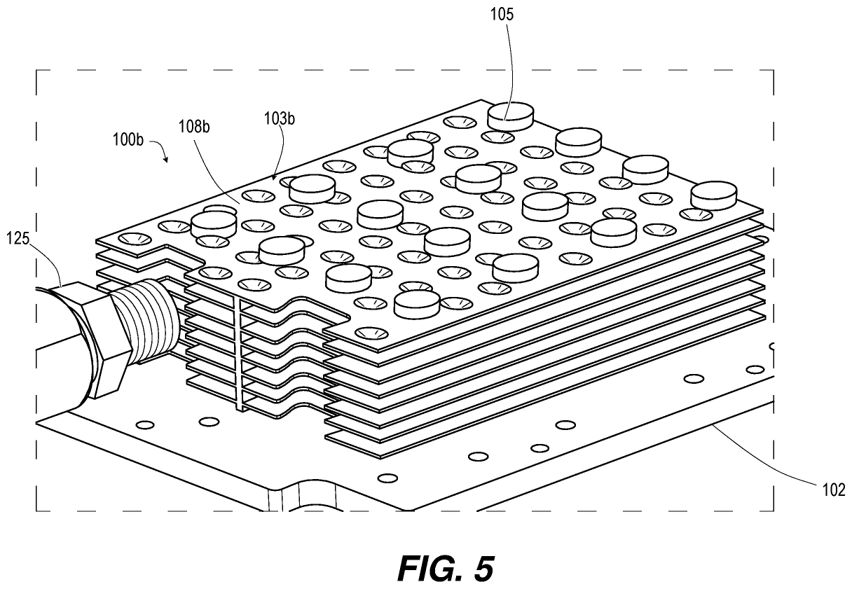

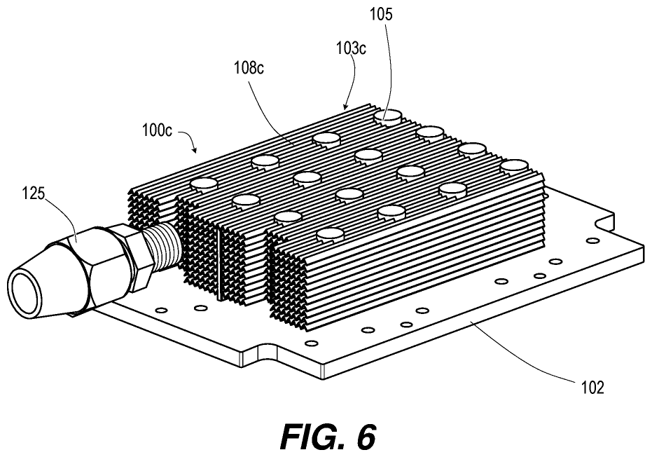

Fins 108 that are flat may be selected for increased liquid flow rate with less turbulent flow. In one or more embodiments, other non-flat geometries may be implemented. FIG. 4 presents a three-dimensional cutaway view of second example cold plate assembly 100a configured with annular disk fins and attached to heat generating electronic component 106 via substrate 107, according to one or more embodiments. Cold plate assembly 100a includes second example fin stack 103a having annular disk fins 108a. FIG. 5 presents a three-dimensional view of cold plate 102 having third example fin stack 103b having dimpled fins 108b. As an additional example of different configurations and types of find stack, FIGS. 6 and 7 present three-dimensional views of cold plate assembly 100c with cold plate 102 having corrugated fins 108c as fourth example fin stack 103c.

FIG. 7 is a three-dimensional cutaway view of cold plate assembly 100c including fourth example fin stack 103c having corrugated fins 108c and cutaway through cold plate 102 to show the hollow interior of orthogonal riser columns 105. Fin stack 103c is attached to heat-generating electronic component 106 (FIG. 1) with substrate 107 being visible. FIG. 8A is side detailed view of a cutaway portion of cold plate 102 and single orthogonal riser column 105 of FIG. 7. FIG. 8B is a three dimension view of hollow interior cavity 807 of single orthogonal riser column 105 of FIG. 7. With particular reference to FIG. 8A, sealed fluid cavity 805 within cold plate 102 is in fluid communication with hollow interior cavity 807 within orthogonal riser column 105 and is partially filled with saturated working fluid 809. Saturated working fluid 809 exists in a liquid state at the base of each orthogonal riser column 105. When/while receiving thermal energy from heat generating electronic component 106 through first surface 114 of cold plate 102, some of saturated working fluid 809 vaporizes or evaporates as gas 811 that rises within hollow interior cavity 807 of riser column 105 and eventually condenses as liquid droplets 813 that return (by gravitational force) to the bottom of sealed fluid cavity 805. Condensation occurs on the sides and top surfaces of riser column as the heat from the rising vapor is absorbed by the connected fins and is removed by the external flow of cooling liquid. As the vapor cools, the vapor undergoes a phase change from gas back to liquid. The cutaway portion exposes interior aspects of the riser columns that may be common to each embodiment of cold plate 102 depicted in FIGS. 1-7. Thermal energy gained at the base of sealed fluid cavity 805 from the heat generating electronic device is transferred up through hollow interior cavity 807 of orthogonal riser column 105 via evaporation of saturated working fluid 809 and then expelled into the fins and eventually the cooling liquid causing condensation of the vapor form of saturated working fluid 809.

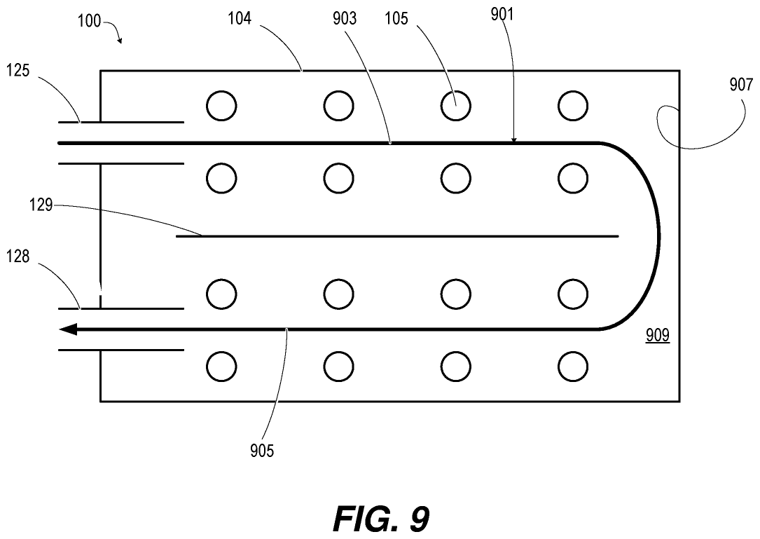

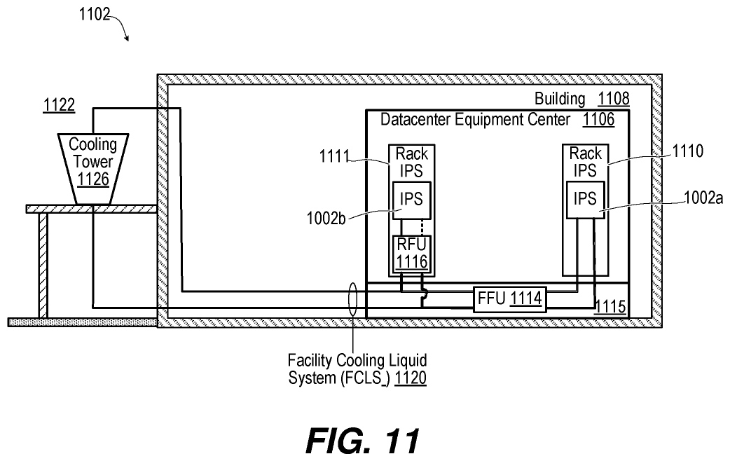

With reference to FIGS. 1-7, each cold plate assembly 100 (FIG. 1), 100a (FIG. 4), 100b (FIG. 5), and 100c (FIG. 6) includes intake port 125 and exhaust port 128 adjacent to each other on one lateral side of encapsulating lid 104. To facilitate a “horse shoe” shaped liquid flow pattern, each fin stake 103 (FIG. 1), 103a (FIG. 4), 103b (FIG. 5), and 103c (FIG. 11) includes a central vertical baffle 129. FIG. 9 is a top view diagram of horse shoe shaped liquid flow 901 with parallel but oppositely flowing intake flow 903 and exhaust flow 905. Liquid cooling cavity 907 provided by an interior of encapsulating lid 104 includes redirection space 909 beyond central vertical baffle 129 and opposite to intake port 125 and exhaust port 128 to redirect intake flow 903 to exhaust flow 905.

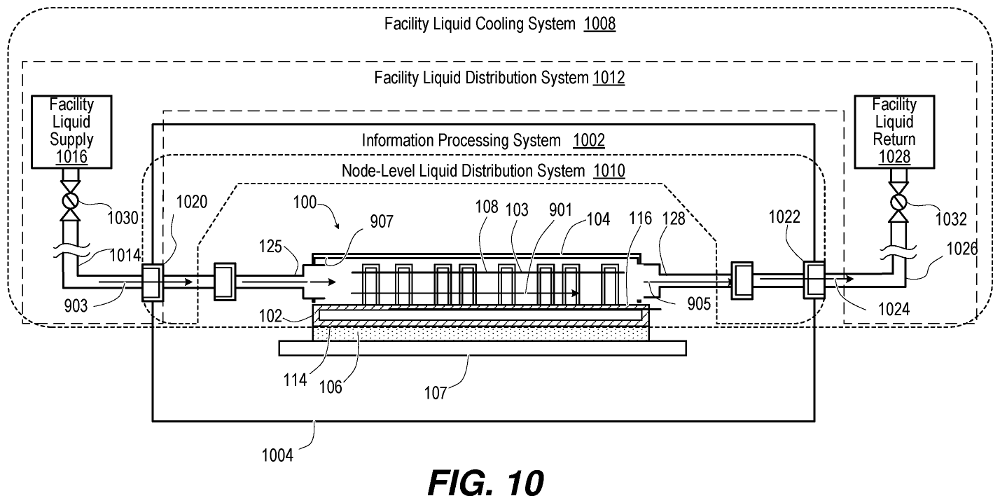

In one or more embodiments, as shown by FIG. 10, intake port 125 and exhaust port 128 may be opposite lateral sides without needing a baffle. In one or more embodiments, intake port 125 and exhaust port 128 may be positioned on adjacent lateral sides. FIG. 10 is a diagram of information processing system (IPS) 1002, which may be located in a node of an information processing system rack (see FIG. 11). IPS 1002 includes one or more heat generating electronic component, such as example heat generating electronic component 106. Liquid cooling system 1008 provides cooling liquid flow 901 to cold plate assembly 100 to cool one or more heat generating electronic component 106. Liquid cooling system 1008 includes node-level liquid distribution system 1010 within node enclosure 1004. Liquid cooling system 1008 includes rack level and/or data center level liquid distribution system, which are external to IPS 1002 and node enclosure 1004. For simplicity, rack level and/or data center level liquid distribution system will collectively be referred to as facility liquid distribution system 1012 to distinguish from the node-level liquid distribution system 1010. Facility liquid distribution system 1012 includes supply distribution conduit 1014 sealably coupled to facility liquid supply 1016 via intake port 1020 for liquid transfer to provide unheated facility liquid, such as water, to intake port 125 of node-level liquid distribution system 1010. Exhaust port 128 of node-level liquid distribution system 1010 returns heated liquid flow 1024 that has passed through cold plate assembly 100. Facility liquid distribution system 1012 includes return distribution conduit 1026 sealably coupled to exhaust port 1022 for liquid transfer to facility liquid return 1028. Encapsulating lid 104 is configured to sealably couple for fluid flow via liquid conduits (i.e., node-level liquid distribution system 1010 and facility liquid distribution system 1012) from facility liquid supply 1016 and to facility liquid return 1028. Liquid flow through liquid cooling system 1008 may be controlled by a binary or proportional electrically actuated supply valve 1030 that is incorporated into supply distribution conduit 1014. Alternatively, or in addition, liquid flow through liquid cooling system 1008 may be controlled by a binary or proportional electrically actuated return valve 1032 that is incorporated into return distribution conduit 1026.

Accordingly, one aspect of the disclosure provides information processing system 1002 that includes heat generating electronic component 106. Information processing system 1002 includes cold plate assembly 100 attached to heat generating electronic component 106 via first surface 114 of cold plate 102. One or each of exterior surface of riser columns 105, fin stack 103, and second surface 116 of cold plate 102 are coated with at least one of a hydrophobic, a non-conductive, and an anti-corrosive surface treatment. Fin stack 103 supports use of unheated facility liquid and provide heat transfer directly to unheated facility liquid without requiring a secondary coolant loop and without causing corrosion or clogging due to facility liquid particulates or chemical contaminants. In one or more embodiments, cold plate assembly 100 further includes encapsulating lid 104 attachable to second surface 116 encompassing at least riser columns 105 with fin stack 103 to form liquid cooling cavity 907 and comprising intake port 125 and exhaust port 128 for coupling to facility liquid supply 1016. In one or more embodiments, cold plate 102 includes a thermally conductive material, and the coating on riser columns 105 and fin stack 103 is both non-conductive and anti-corrosive. In one or more particular embodiments, riser columns 105 and fin stack 103 are further coated by a hydrophobic layer to prevent scaling and sedimentation due to dissolved calcium carbonate in the facility liquid from facility liquid supply 1016.

Aspects of the present disclosure may be applied to an edge mobile datacenter or facility with a single rack IPS. Additionally, aspects of the present disclosure may also be applied to an enterprise datacenter having multiple buildings and rooms with tens, hundreds, or thousands of rack IPSes.

FIG. 11 is a diagram of a first example liquid cooling system that supports a datacenter equipment center with rack-level liquid cooling of heat generating electronic components, each utilizing an attached one of the environmentally hardened cold plate assembly of FIG. 1, and utilizing one liquid cooling loop for heat exchange, according to one or more embodiments. In the provided example, datacenter equipment center 1106 within building 1108 includes two rack information processing systems (IPSes) 1110 and 1111 that have information processing systems (IPSes) 1002a and 1002b respectively, which receive liquid cooling by respective ones of cold plate assembly 100 (as presented in FIG. 10). In one or more embodiments, rack IPS 1110 is supported by floor filtration unit (FFU) 1114 in floor space 1115 of datacenter equipment center 1106. Rack IPS 1111 is supported by rack filtration unit (RFU) 1116. Liquid cooling system 1102 includes a single liquid cooling loop, facility cooling liquid system (FCLS) 1120. FCLS 1120 circulates facility liquid from cooling tower 1126 (or a facility supply) through conduits to the data center and IPSes in rack IPS, and from each cold plate back to cooling tower 1126 (or facility return) to dissipate thermal energy to ambient air 1122. Utilization of cold plate assembly 100 to provide liquid cooling of heat generating components within the data center (as shown in FIG. 10) eliminates the need for use of purified liquid in a separated rack level technology cooling system and the multiple separated cooling loops to provide reliable operation of a liquid cooling system.

Aspects of the present disclosure may be applied to multiple cooling loop systems. In an example, a liquid cooling system may include four isolated liquid cooling loops in series, a technology cooling system (TCS), a facility cooling liquid system (FCLS), and a condenser liquid system that support rack IPSes. A chiller loop may be counted as an additional liquid cooling loop. TCS is supported by a cooling distribution unit (CDU) that circulates liquid coolant through an IPS via a closed loop. CDU transfers thermal energy from the TCSs to facility cooling liquid such as unpurified water provided by a facility cooling system (FCLS). In an example, FCLS may transfer exhaust thermal energy directly into ambient air via a cooling tower. The liquid cooling system may further include a condenser liquid system (CLS) that circulates cooling water through the cooling tower. The liquid cooling system may further include the chiller loop (or chiller) that stores a thermal buffering quantity of liquid such as water. The chiller circulates the water through a first liquid-to-liquid heat exchanger to receive thermal energy from FCLS. The chiller circulates the heated water through a second liquid-to-liquid heat exchanger to transfer thermal energy to the CLS. The chiller enables intermittent use of the cooling tower while maintaining water in the chiller within a temperature range suitable for both FCLS and CLS. Utilization of a cold plate assembly to provide liquid cooling of heat generating components within the data center eliminates the need for use of purified liquid in a separated rack level technology cooling system and the multiple separated cooling loops to provide reliable operation of the liquid cooling system. An existing data center cooling system can be retrofitted with IPSes that are configured with a plurality of a cold plate assembly as the mechanism for colling the heat generating components within the IPS racks and replace the more expensive purified cooling liquids within the technology cooling system loop, without having issues related to fouling of the cold plates with the switch to utilizing normal, facility rated liquid supply.

FIG. 12 presents an example physical vapor deposition (PVD) process by which a protective coating can be deposited liquid cooling component 1203 to generate/manufacture environmentally hardened (or coated) surfaces to protect liquid cooling component 1203 from damage, deterioration, and/or clogging due to exposure to facility-grade cooling liquids that can contain corrosive chemical and particulate contaminants. An example of liquid cooling component 1203 is cold plate 102 with riser columns 105 (FIG. 1). Another example of liquid cooling component 1203 is fin 108 (FIG. 1), fin 108a (FIG. 4), fin 108b (FIG. 5), or fin 108c (FIG. 6). An additional example liquid cooling component 1203 is liquid cooling cavity 907 of encapsulating lid 104 (FIG. 9). To facilitate use of a facility cooling liquid, such as unpurified water, liquid cooling component 1203 is environmentally hardened, such as by applying a coating in physical vapor deposition (PVD) apparatus 1201. PVD apparatus 1201 includes vapor chamber 1218 that is filled with sputtering gas 1220 received from sputtering gas supply 1222 and that is maintained at an appropriate pressure by vacuum system 1224 that removes excess gas 1225. Upward oriented surface 1223 of liquid cooling component 1203 is engaged to substrate holder 1226, which is connected to electrical ground 1227. Downward oriented surface 1231 of liquid cooling component 1203 is oriented toward target 1228, which includes one or more coating materials to be deposited onto downward oriented surface 1231 of liquid cooling component 1203 by PVD. Target 1228 is connected to power supply 1230 to cause ionization of sputtered atoms 1232, 1234, and 1236, which are attracted by the voltage difference between target 1228 and liquid cooling component 1203 to that transit across vacuum chamber 1218 and be deposited onto downward oriented surface 1231 of liquid cooling component 1203 to form a protective coating. In an example, first atom 1232 represents a hydrophobic material, second atom 1234 represents a non-conductive material, and third atom 1236 represents an anti-corrosive material. Wetted surfaces cold plate 102 and fin stack 103 are coated with non-conductive, anti-corrosion surface enhancements such as Zirconium Nitride, Titanium Nitride, and other ceramics applied by PVD. In one or more embodiments, the surface may also be coated with a hydrophobic surface treatment to mitigate scale and sedimentation. The specific description of PVD as the process is thus not intended to be limiting on the scope of the disclosure. To coat all wetted surface of liquid cooling component 1203, liquid cooling component 1203 may be processed by PVD while in more than one orientation so that each wetted surface is coated.

It is appreciated that while the coating process is shown to be completed by PVD, other similar techniques can be utilized to provide the coating layer(s) on the first surface of cold plate to yield the various physical and chemical enhancements that are described herein. In an example, liquid cooling component 1203 or an assembly of liquid cooling components 1203 may be dipped or immersed into liquid that provides the surface treatment.

Facility water, which may contain corrosive chemical and particulate contaminants would be suboptimal for liquid cooling using conventional cold plates. In one or more embodiments, the protective coating applied to the cold plate by the above-described PVD process provides one or more protective characteristics, including: (i) a hydrophobic characteristic to mitigate scaling by calcium carbonate, (ii) an anti-corrosive characteristic to mitigate formation corrosion, and (iii) a non-conductive characteristic to mitigate rusting. Cold plate 102 and fin stack 103 covered with the resulting coating is designed to resist heat-transfer inhibiting failure modes common to liquid cooling with poorly regulated water quality, namely suspended solid particulates, biological growth potential, and harsh water chemistry conditions, including semi-corrosive mixtures.

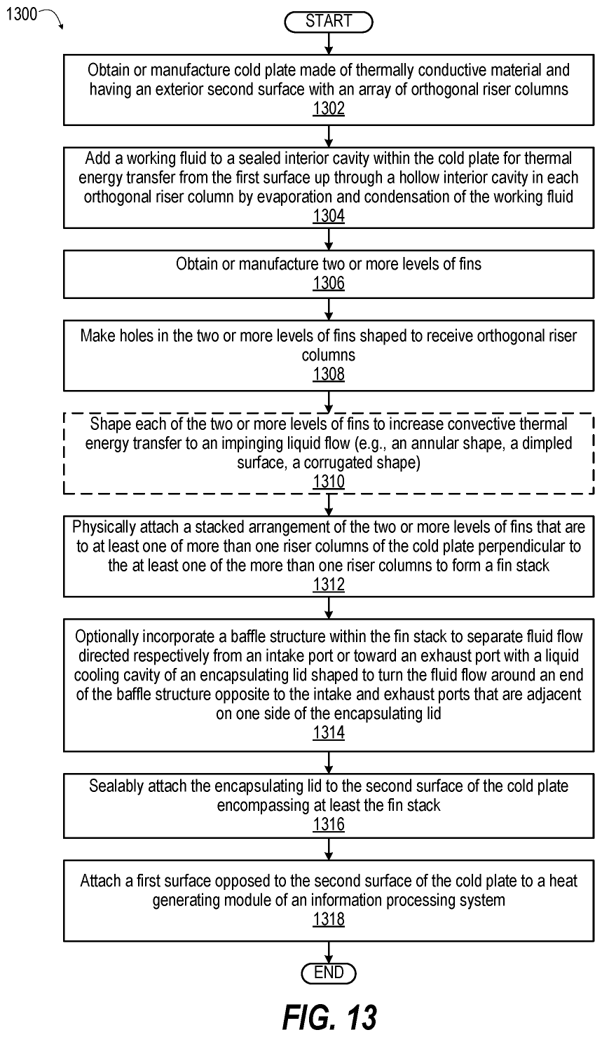

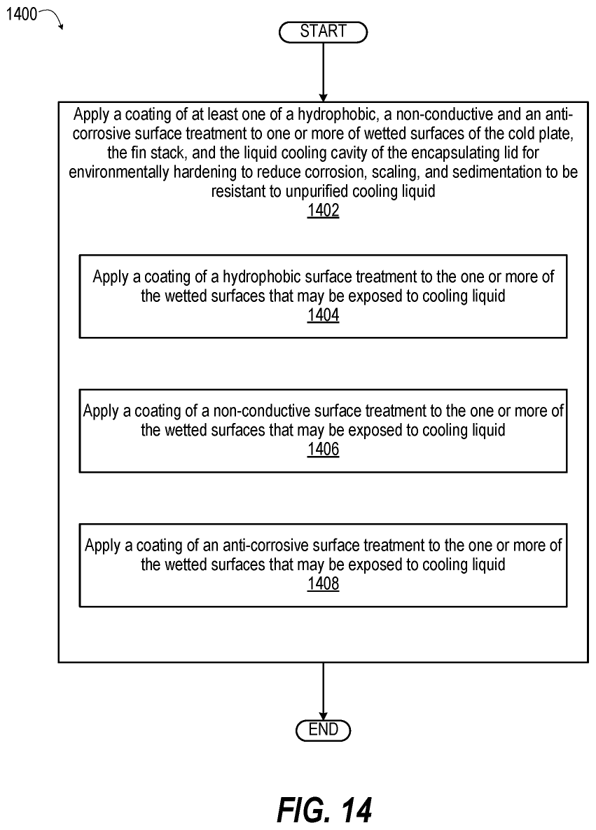

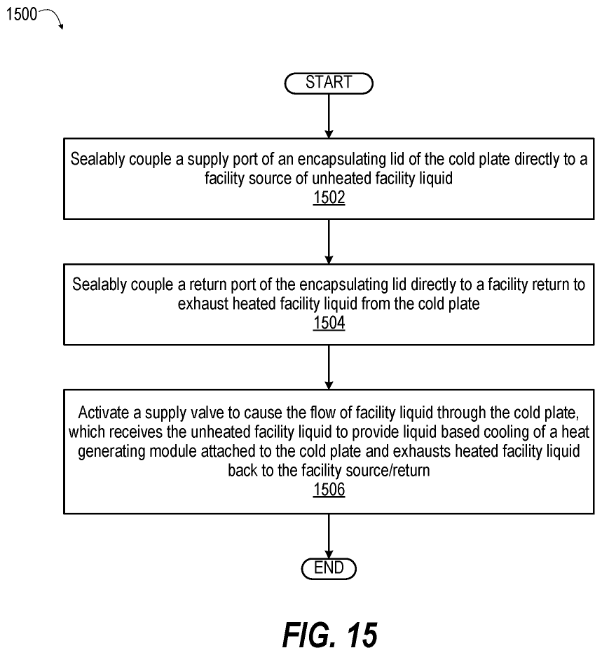

FIG. 13 is a flow diagram presenting method 1300 of manufacturing a cold plate assembly having increased thermal energy dissipation capabilities of a fin stack and phase change vapor chambers. FIG. 14 is a flow diagram presenting method 1400 that augments method 1300 (FIG. 13) to environmentally hardening a fin stack and other wetted surfaces of the cold plate assembly that may be exposed to cooling liquid to enable utilizing facility liquid for liquid cooling of heat generating electronic components without experiencing issues of fouling or clogging. FIG. 15 is a flow diagram presenting method 1500 of using a cold plate assembly to liquid cool heat generating components of an information processing system. The descriptions of method 1300 (FIG. 13), method 1400 (FIG. 14) and method 1500 (FIG. 15) are provided with general reference to the specific components illustrated within the preceding FIGS. 1-12. Specific components referenced in method 1300 (FIG. 13), method 1400 (FIG. 14) and method 1500 (FIG. 15) may be identical or similar to components of the same name used in describing preceding FIGS. 1-12. In one or more embodiments, an assembly controller of an automated control system or a similar computing device provides the described functionality of method 1300 (FIG. 13), method 1400 (FIG. 14) and method 1500 (FIG. 15).

With reference to FIG. 13, in one or more embodiments, method 1300 optionally includes obtaining or manufacturing a cold plate made of a thermally conductive material and having an exterior second surface with an array of hollow orthogonal riser columns (block 1302). In one or more embodiments, the cold plate has a sealed fluid cavity between a first surface and the second surface opposite the first surface. Each orthogonal riser column has a hollow interior cavity that is in fluid communication with the sealed fluid cavity for evaporation and condensation. Method 1300 includes adding a saturated working fluid to a sealed fluid cavity within the cold plate for thermal energy transfer from the first surface up through a hollow interior cavity in each orthogonal riser column by evaporation and condensation of the saturated working fluid (block 1304). In one or more alternate embodiments, method 1300 includes manufacturing each riser column with a sealed interior cavity having an internal saturated working fluid that is independent of the working fluid in the adjacent riser columns. Specifically, the cold plate is manufactured with each orthogonal riser column having a hollow space that is filled with the saturated working fluid in a sealed cavity for use as a phase change heat transfer mechanism.

In one or more embodiments, method 1300 includes obtaining or manufacturing two or more levels of fins (block 1306). Method 1300 includes making holes in the two or more levels of fins shaped to receive orthogonal riser columns (block 1308). In one or more embodiments, method 1300 optionally includes shaping each of the two or more levels of fins to increase convective thermal energy transfer to an impinging liquid flow (e.g., an annular shape, a dimpled surface, a corrugated shape) (block 1310). Method 1300 includes physically attaching a stacked arrangement of the two or more levels of fins that are to at least one of more than one riser columns of the cold plate perpendicular to the at least one of the more than one riser columns to form a fin stack (block 1312). The two or more levels are spaced apart and are substantially in parallel with each other.

In one or more embodiments, the intake port and the exhaust ports are adjacent on one side of the encapsulating lid. Method 1300 may further include optionally incorporating a baffle structure within the fin stack to separate fluid flow directed respectively from an intake port or toward an exhaust port, with a liquid cooling cavity of the encapsulating lid shaped to turn the fluid flow around an end of the baffle structure opposite to the intake and exhaust ports (block 1314). Method 1300 includes sealably attaching the encapsulating lid to the second surface of the cold plate, encompassing at least riser columns and the fin stack (block 1316). Sealably attaching the encapsulating lid to the cold plate may include use of one or more of a press-fit interference attachment, adhering with an adhesive or adhesive layer, soldering, brazing, welding, and fastener attachment. The encapsulating lid forms a liquid cooling cavity and includes an intake port and an exhaust port for coupling (for supply and return) to a facility liquid source. With the cold plate assembly completed, method 1300 optionally includes attaching a first surface opposed to the second surface of the cold plate to a heat generating electronic component of an information processing system (block 1318). The resulting heat generating electronic component can then be liquid cooled during operation by attaching a first conduit from a liquid supply to the intake port and a second conduit from the exhaust port to the exhaust return port of the liquid return. Then, method 1300 ends.

In one or more embodiments, the cold plate is manufactured by utilizing copper as the thermally conductive material. The first surface of the cold plate is a heat receiving surface for attaching to a heat generating electronic component. The second surface of the cold plate is a heat transfer surface. In one or more embodiments, in manufacturing the cold plate, method 1300 further includes configuring the fin stack with the levels of fins spaced apart at least 800-microns to facilitate passage of the facility liquid particulates. In one or more embodiments, in manufacturing the cold plate assembly, method 1300 further includes configuring a geometry of the fin stack to maintain large hydraulic diameters with greater than 800-micron flow spaces. In one or more embodiments, in manufacturing the encapsulating lid of the cold plate assembly, method 1300 further includes configuring the intake port, exhaust port, and volumetric space of the liquid cooling cavity to maintain a flow velocity of at least 0.7 m/s of liquid impinging the fin stack to prevent sedimentation.

With reference to FIG. 14, method 1400 may further include applying a coating of at least one of a hydrophobic, a non-conductive and an anti-corrosive surface treatment to one or more of wetted surfaces of the cold plate with the riser columns, the fins of the fin stack, and the liquid cooling cavity of the encapsulating lid for environmentally hardening of the surfaces to reduce corrosion, scaling, and sedimentation to be resistant to chemical impurities and particulates within unpurified cooling liquid (block 1402). In an example, method 1400 includes applying a coating of a hydrophobic surface treatment to the one or more of the wetted surfaces that may be exposed to cooling liquid (block 1404). In another example, method 1400 includes applying a coating of a non-conductive surface treatment to the one or more of the wetted surfaces that may be exposed to cooling liquid (block 1406). In an additional example, method 1400 includes applying a coating of an anti-corrosive surface treatment to the one or more of the wetted surfaces that may be exposed to cooling liquid (block 1408). The coating protects the surface material and thereby allows direct use of facility liquid or facility-grade liquid that may contain corrosive chemical or clogging particulates. With the use of environmentally hardened or coated cold plate assembly (100), isolating the facility liquid in a separate cooling loop from a secondary coolant loop that directly cools the heat generating component is not required. The facility liquid provides direct liquid transfer of heat from a heat generating component to which the cold plate is attached. The coating avoids or mitigates corrosion and clogging of the cold plate due to facility liquid chemicals and/or particulates. Then, method 1400 ends.

In one or more embodiments, as presented in blocks 1404, 1406, and 1408, applying the coating may include only one of the three characteristics (i.e., hydrophobic, non-conductive, and anti-corrosive) in a coating, two of the three characteristics in the coating, or all three of the characteristics in a coating. In one or more embodiments, as presented in blocks 1404, 1406, and 1408, applying the coating may further includes coating the one or more of the wetted surfaces that may be exposed to cooling liquid with more than one coating of surface treatment, each coating providing one or more of the three characteristics. In one or more embodiments, as presented in block 1404, coating the one or more of the wetted surfaces that may be exposed to cooling liquid includes applying a hydrophobic layer to prevent scaling and sedimentation due to dissolved calcium carbonate in the facility liquid. In one or more embodiments, method 1400 further includes coating the one or more of the wetted surfaces that may be exposed to cooling liquid using physical vapor deposition (PVD). In one or more embodiments, method 1400 further includes coating the one or more of the wetted surfaces that may be exposed to cooling liquid, via PVD, with one or more ceramics from among a group comprising Zirconium Nitride and Titanium Nitride.

With reference to FIG. 15, method 1500 includes sealably coupling a supply port of an encapsulating lid of the cold plate directly (or indirectly through a supply manifold) to a cooling liquid source of unheated facility liquid (block 1502). Method 1500 includes sealably coupling a return port of the encapsulating lid directly (or indirectly through a return manifold) to a facility return to exhaust heated facility liquid from the cold plate (block 1504). Method 1500 includes activating a supply valve to cause the flow of facility liquid through the cold plate, which receives the unheated facility liquid to provide liquid based cooling of a heat generating electronic component attached to the cold plate and directs the heated facility liquid back to the cooling liquid source or to a cooling liquid return (block 1506). Then, method 1500 ends.

In one or more embodiments, the facility liquid can contain at least one of particles and chemical contaminants. The NCAC coating of the wetted surfaces, including the riser columns, fins of the fin stack, and other interior surfaces of the cold plate enables direct use of facility liquid and provides heat transfer directly to the facility liquid without requiring a secondary coolant loop and without causing corrosion or clogging of the cold plate due to facility liquid contaminants or particulates. In one or more embodiments, the cold plate is made from a thermally conductive material, having a first surface attachable to the heat generating electronic component of an information processing system, and having a second surface opposed to the first surface. The fin stack and the second surface, which is configured with the array of orthogonal riser columns have exterior surfaces that are coated with at least one of a non-conductive and an anti-corrosive surface treatment, preventing corrosion and/or clogging of the cold plate due to facility liquid contaminants and/or particulates. In one or more embodiments, the fins of the fin stack are spaced apart at least 800-microns to facilitate passage of the facility liquid particulates.

Aspects of the present innovation are described above with reference to flowchart illustrations and/or block diagrams of methods, apparatus (systems) and computer program products according to embodiments of the innovation. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

As will be appreciated by one skilled in the art, embodiments of the present innovation may be embodied as a system, device, and/or method. Accordingly, embodiments of the present innovation may take the form of an entirely hardware embodiment or an embodiment combining software and hardware embodiments that may all generally be referred to herein as a “component”, “circuit,” “module” or “system.”

While the innovation has been described with reference to exemplary embodiments, it will be understood by those skilled in the art that various changes may be made, and equivalents may be substituted for elements thereof without departing from the scope of the innovation. In addition, many modifications may be made to adapt a particular system, device, or component thereof to the teachings of the innovation without departing from the essential scope thereof. Therefore, it is intended that the innovation not be limited to the particular embodiments disclosed for carrying out this innovation, but that the innovation will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the innovation. As used herein, the singular forms “a”, “an” and “the” are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present innovation has been presented for purposes of illustration and description but is not intended to be exhaustive or limited to the innovation in the form disclosed. Many modifications and variations will be apparent to those of ordinary skill in the art without departing from the scope and spirit of the innovation. The embodiments were chosen and described in order to best explain the principles of the innovation and the practical application, and to enable others of ordinary skill in the art to understand the innovation for various embodiments with various modifications as are suited to the particular use contemplated.

What is claimed is:

1. A cold plate assembly comprising:
a cold plate comprised of a thermally conductive material, the cold plate having a first surface attachable to a heat generating electronic component of an information processing system and having a second surface opposite to the first surface and comprising an array of more than one riser columns extending orthogonally from the second surface of the cold plate;
a stacked arrangement of two or more levels of fins that are physically attached to at least one of the more than one riser columns perpendicular to the at least one of the more than one riser columns, the two or more levels spaced apart, substantially in parallel with each other and with the second surface to form a fin stack; and
an encapsulating lid attachable to the second surface to form a liquid cooling cavity that encloses the fin stack and comprising an intake port and an exhaust port that are laterally positioned and aligned with the fin stack to create liquid flow through the fin stack for liquid cooling.

2. The cold plate assembly of claim 1, wherein each of the one or more fins of the fin stack comprises a flat geometric shape configured to increase rate of liquid flow through the fin stack and mitigate sedimentation and scaling.

3. The cold plate assembly of claim 1, wherein each of the one or more fins of the fin stack comprises a non-flat geometric shape configured to increase convection heat transfer performance.

4. The cold plate assembly of claim 3, wherein each of the one or more fins of the fin stack comprises a dimpled shape configured to increase convection heat transfer performance.

5. The cold plate assembly of claim 3, wherein each of the one or more fins of the fin stack comprises a corrugated shape configured to increase convection heat transfer performance.

6. The cold plate assembly of claim 3, wherein each of the one or more fins of the fin stack comprises an annular disk attached to a single one of the more than one riser columns.

7. The cold plate assembly of claim 3, wherein each of the one or more fins of the fin stack are physically attached to one or more riser columns via an attachment process from among a group comprising a brazed attachment, a press-fit attachment, a soldered attachment, and an adhesive attachment.

8. The cold plate assembly of claim 1, wherein each riser column comprises a hollow pipe filled with a saturated working fluid to support thermal convection through evaporation and condensation in addition to thermal conduction away from the heat generating electronic component.

9. The cold plate assembly of claim 1, wherein:
the thermally conductive material of the cold plate comprises copper; and
the second surface, the more than one riser columns, and the more than one fins are coated with at least one material that is one or more of hydrophobic, non-conductive, and anti-corrosive to enable use of facility water as a cooling liquid.

10. The cold plate assembly of claim 1, wherein the more than one levels of fins of the fin stack are spaced apart at least 800 microns and the encapsulating lid is configured to maintain a flow velocity of at least 0.7 m/s of liquid impinging the fin stack to prevent sedimentation within the fin stack.

11. An information processing system comprising:
at least one heat generating electronic component; and
a cold plate assembly comprising:
a cold plate comprised of a thermally conductive material, the cold plate having a first surface attachable to a heat generating electronic component of an information processing system and having a second surface opposite to the first surface and comprising an array of more than one riser columns extending orthogonally from the second surface of the cold plate;
a stacked arrangement of two or more levels of fins that are physically attached to at least one of the more than one riser columns perpendicular to the at least one of the more than one riser columns, the two or more levels spaced apart, substantially in parallel with each other and with the second surface to form a fin stack; and
an encapsulating lid attachable to the second surface to form a liquid cooling cavity that encloses the fin stack and comprising an intake port and an exhaust port that are laterally positioned and aligned with the fin stack to create liquid flow through the fin stack for liquid cooling.

12. The information processing system of claim 11, wherein each of the one or more fins of the fin stack comprises a flat geometric shape configured to increase rate of liquid flow through the fin stack and mitigate sedimentation and scaling.

13. The information processing system of claim 11, wherein each of the one or more fins of the fin stack comprises a non-flat geometric shape configured to increase convection heat transfer performance.

14. The information processing system of claim 13, wherein each of the one or more fins of the fin stack comprises a dimpled shape configured to increase convection heat transfer performance.

15. The information processing system of claim 13, wherein each of the one or more fins of the fin stack comprises a corrugated shape configured to increase convection heat transfer performance.

16. The information processing system of claim 13, wherein each of the one or more fins of the fin stack comprises an annular disk attached to a single one of the more than one riser columns.

17. The information processing system of claim 13, wherein each of the one or more fins of the fin stack are physically attached to one or more riser columns via an attachment process from among a group comprising a brazed attachment, a press-fit attachment, a soldered attachment, and an adhesive attachment.

18. The information processing system of claim 11, wherein each riser column comprises a hollow pipe filled with a saturated working fluid to support thermal convection through evaporation and condensation in addition to thermal conduction away from the heat generating electronic component.

19. The information processing system of claim 11, wherein:
the thermally conductive material of the cold plate comprises copper; and
the second surface, the more than one riser columns, and the more than one fins are coated with at least one material that is one or more of hydrophobic, non-conductive, and anti-corrosive to enable use of facility water as a cooling liquid.

20. The information processing system of claim 11, wherein the more than one levels of fins of the fin stack are spaced apart at least 800 microns and the encapsulating lid is configured to maintain a flow velocity of at least 0.7 m/s of liquid impinging the fin stack to prevent sedimentation within the fin stack.

21. A data center comprising:
an information processing system rack comprising:
an information processing system comprising:
at least one heat generating electronic component; and
a cold plate assembly comprising:
a cold plate comprised of a thermally conductive material, the cold plate having a first surface attachable to a heat generating electronic component of an information processing system and having a second surface opposite to the first surface and comprising an array of more than one riser columns extending orthogonally from the second surface of the cold plate;
a stacked arrangement of two or more levels of fins that are physically attached to at least one of the more than one riser columns perpendicular to the at least one of the more than one riser columns, the two or more levels spaced apart, substantially in parallel with each other and with the second surface to form a fin stack; and
an encapsulating lid attachable to the second surface to form a liquid cooling cavity that encloses the fin stack and comprising an intake port and an exhaust port that are laterally positioned and aligned with the fin stack to create liquid flow through the fin stack for liquid cooling.

22. The data center of claim 21, further comprising:
a facility source of facility cooling liquid, the facility source comprising a facility outlet port and a facility return port; and
an open-loop liquid distribution system sealably connected between the intake port of the cold plate assembly and an outlet port of the facility source to channel unheated facility water to the cold plate assembly and between the exhaust port of the cold plate assembly and the facility return port to channel heated exhaust water from the cold plate assembly to the facility return port.

23. The data center of claim 22, wherein the open-loop liquid distribution system comprises:
a rack liquid cooling manifold system comprising:
a supply manifold comprising a supply control valve and a manifold intake port available for sealably coupling to a facility water supply to receive a cooling liquid and comprising more than one server supply ports each available for sealably coupling, for liquid transfer of the cooling liquid, to a respective cooling liquid supply input of a corresponding information processing system node supported by a rack frame capable of supporting multiple information processing system nodes, each having one or more heat-generating electronic components; and
a return manifold comprising a facility water return port for sealably coupling to a facility return to exhaust the cooling liquid and comprising more than one server return ports, each available for sealably coupling, for exhaust liquid transfer, to a respective cooling liquid exhaust output of the corresponding information processing system node, the respective cooling liquid exhaust output and a paired supply liquid cooling input directing cooling liquid flow through one or more cold plate assembly positioned within the corresponding information processing system node to thermally cool the one or more heat-generating electronic components.

24. The data center of claim 23, wherein the open-loop liquid distribution system further comprises a plurality of conduits that sealably couple for liquid transfer: (i) the more than one server supply ports of the supply manifold to the corresponding server supply inputs of the more than one information processing system nodes; (ii) the corresponding server supply input to the one or more cold plate assemblies in the corresponding information processing system node; (iii) the one or more cold plate assemblies in the corresponding information processing system node to the corresponding server return output; and (iv) and the more than one server return outputs to the server return ports of the return manifold.

25. A method of manufacturing a stacked fin cold plate for providing liquid cooling of heat generating electronic components, the method comprising:
physically attaching a stacked arrangement of two or more levels of fins that are to at least one of more than one riser columns of a cold plate perpendicular to the at least one of the more than one riser columns, the two or more levels spaced apart and substantially in parallel with each other to form a fin stack, the cold plate comprised of a thermally conductive material, the cold plate having a first surface attachable to a heat generating electronic component of an information processing system and having a second surface substantially in parallel to the fin stack, opposite to the first surface, and comprising the more than one riser columns extending orthogonally from the second surface of the cold plate; and
attaching an encapsulating lid to the second surface to form a cold plate assembly having a liquid cooling cavity that encloses the fin stack and comprising an intake port and an exhaust port that are laterally positioned and aligned with the fin stack to create liquid flow through the fin stack for liquid cooling.

26. The method of claim 25, further comprising configuring each of the one or more fins of the fin stack to have a flat geometric shape to increase rate of liquid flow through the fin stack and mitigate sedimentation and scaling.

27. The method of claim 25, further comprising configuring each of the one or more fins of the fin stack to have a non-flat geometric shape to increase convection heat transfer performance.

28. The method of claim 25, further comprising configuring each of the one or more fins of the fin stack to have a dimpled shape to increase convection heat transfer performance.

29. The method of claim 25, further comprising configuring each of the one or more fins of the fin stack to have a corrugated shape to increase convection heat transfer performance.

30. The method of claim 25, further comprising configuring each of the one or more fins of the fin stack as an annular disk that is attached to a single one of the more than one riser columns.

31. The method of claim 25, further comprising physically attaching each of the one or more fins of the fin stack to one or more riser columns by an attachment process from among a group comprising brazing, press-fitting, soldering, and adhering via an adhesive.

32. The method of claim 25, further comprising configuring each riser column to be a hollow pipe filled with a saturated working fluid to support thermal convection through evaporation and condensation in addition to thermal conduction away from the heat generating electronic component.

33. The method of claim 25, wherein the thermally conductive material used to form the cold plate comprises copper.

34. The method of claim 25, further comprising:
coating the second surface, the more than one riser columns, and the more than one fins with at least one material that is one or more of hydrophobic, non-conductive, and anti-corrosive to enable use of facility water as a cooling liquid without clogging or fouling interior surfaces of the cold plate assembly.

35. The method of claim 25, further comprising configuring the more than one levels of fins of the fin stack to be spaced apart at least 800 microns and the encapsulating lid is configured to maintain a flow velocity of at least 0.7 m/s of liquid impinging the fin stack to prevent sedimentation within the fin stack.
